(19) United States
(12) Patent Application Publication
(10) Pub. No.: US 2013/0057337 A1
(43) Pub. Date: Mar. 7, 2013

(54) NOISE CANCELLATION APPARATUS AND METHOD FOR CANCELING NOISE

(71) Applicant: Min-Soo KANG, Seoul (KR)

(72) Inventor: Min-Soo KANG, Seoul (KR)

(73) Assignee: PANTECH CO., LTD., Seoul (KR)

(21) Appl. No.: 13/435,744

(22) Filed: Mar. 30, 2012

(30) Foreign Application Priority Data
Sep. 2, 2011 (KR) 10-2011-0089205

(51) Int. Cl. H03K 17/16

(52) U.S. Cl. 327/551

(57) ABSTRACT

A noise cancellation apparatus for an electrostatic capacity type touch panel includes a first grounding unit that provide an internal ground and a second grounding unit that provides an external ground. If the noise detected in the touch panel exceeds a reference value, the first grounding unit is connected to the second grounding unit. The second grounding unit is connected to a metallic component of a case of a terminal device housing the electrostatic capacity type touch panel and provides an external ground through a contact with user of the terminal device.

### CROSS-REFERENCE TO RELATED APPLICATION

This application claims priority from and the benefit under 35 U.S.C. §119(a) of Korean Patent Application No. 10-2011-0089205, filed on Sep. 2, 2011, which is herby incorporated by reference for all purposes as if fully set forth herein.

### BACKGROUND

1. Field

The following description relates to a noise cancellation apparatus and method for noise cancellation in an electrostatic capacity type touch panel.

2. Discussion of the Background

An electrostatic capacity type touch screen includes a glass plate having special transparent conductive electrodes coated on both surfaces. Upon applying a voltage on each corner of the touch screen, a high frequency is created on a surface of the touch screen, and a controller analyzes a high-frequency waveform that changes in response to touch by a finger, thereby recognizing a point or location touched on the touch screen. In the electrostatic capacity type touch screen, electrostatic capacity changes with a distance from the electrode to a body part close to the touch screen. As a distance between the electrode and the body part is shortened, the measured electrostatic capacity increases, and as the distance is increased, the measured electrostatic capacity decreases. Such an electrostatic capacity type touch screen is affected by external noise, and thus may not accurately measure an electrostatic capacity change in relation to a distance between the touch screen and the body part, which may cause an erroneous or unintended operation.

The above information disclosed in this Background section is only for enhancement of understanding of the background of the invention and therefore it may contain information that does not form any part of the prior art.

### SUMMARY

Exemplary embodiments of the present invention provide a noise canceling apparatus for an electrostatic capacity type touch panel.

Exemplary embodiments of the present invention also provide a method for noise reduction or cancellation in an electrostatic capacity type touch panel.

Additional features of the invention will be set forth in the description which follows, and in part will be apparent from the description, or may be learned by practice of the invention.

An exemplary embodiment of the present invention discloses a noise cancellation apparatus of an electrostatic capacity type touch panel, including: a noise sensing unit to sense noise in the electrostatic capacity type touch panel; a first grounding unit to provide an internal ground to the electrostatic capacity type touch panel if a noise is sensed; a second grounding unit to provide an external ground to the electrostatic capacity type touch panel if a noise is sensed.

An exemplary embodiment of the present invention also discloses a method for canceling noise in a touch panel, including: sensing a noise by a sensing unit; generating a noise indicator to indicate the occurrence of the noise; generating a switching signal to connect a first grounding unit to a second grounding unit; connecting the first grounding unit to the second grounding unit; if a noise is no longer detected, disconnecting the first grounding unit from the second grounding unit.

It is to be understood that both the foregoing general description and the following detailed description are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this specification, illustrate embodiments of the invention, and together with the description serve to explain the principles of the invention.

FIG. 1 is a block diagram of a configuration of a noise cancellation apparatus according to an exemplary embodiment of the invention.

FIG. 2 is a schematic diagram of an external metal case of a terminal device according to an exemplary embodiment of the invention.

FIG. 3 is a schematic diagram illustrating a second grounding unit according to an exemplary embodiment of the invention.

FIG. 4 is a flowchart illustrating a method for canceling noise according to an exemplary embodiment of the invention.

### DETAILED DESCRIPTION OF THE ILLUSTRATED EMBODIMENTS

The invention is described more fully hereinafter with references to the accompanying drawings, in which exemplary embodiments of the invention are shown. This invention may, however, be embodied in many different forms and should not be construed as limited to the embodiments set forth herein. Rather, these exemplary embodiments are provided so that this disclosure is thorough, and will fully convey the scope of the invention to those skilled in the art. Throughout the drawings and the detailed description, unless otherwise described, the same drawing reference numerals are understood to refer to the same elements, features, and structures. The relative size and depiction of these elements may be exaggerated for clarity, illustration, and convenience.

It will be understood that when an element or layer is referred to as being “connected to” another element, it can be directly on or directly connected to the other element, or intervening elements or layers may be present. In contrast, when an element is referred to as being “directly connected to” another element, there are no intervening elements present.

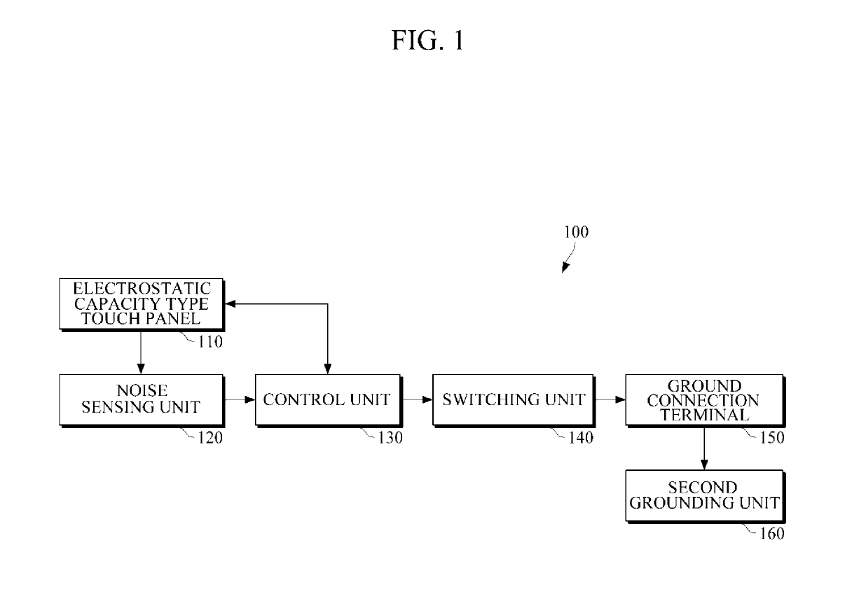

FIG. 1 is a block diagram of a noise cancellation apparatus according to an exemplary embodiment of the invention.

The noise cancellation apparatus 100 may be configured to reduce the effects of noise detected on an electrostatic capacity type touch panel. For the purposes of this specification, “noise cancellation” may refer to noise cancellation, or noise reduction below a reference or threshold value. Here, noise may be any factor that causes erroneous, such as unintended, operation when sensing touch on an electrostatic capacity type touch panel. For example, noise may include an ambient electric field or an ambient magnetic field that affects the sensing of touch of a user on the electrostatic capacity type touch panel. The noise cancellation apparatus 100 may be implemented in terminal devices, for example, smart phones, mobile phones, portable multimedia players (PMPs), personal digital assistants (PDAs), palmtop computers, and the like, that may employ an electrostatic capacity type touch panel.

Referring to FIG. 1, the noise cancellation apparatus 100 may include an electrostatic capacity type touch panel 110, a noise sensing unit 120, a control unit 130, a switching unit 140, a ground connection terminal 150, and a second grounding unit 160.

The electrostatic capacity type touch panel 110 is configured to produce a change in an electrostatic capacity according to a distance of an object or body portion that may approach or touch the electrostatic capacity type touch panel 110.

The noise sensing unit 120 may detect noise generated from the electrostatic capacity type touch panel 110. The noise sensing unit 120 may set a reference threshold electrostatic capacity value with respect to the electrostatic capacity type touch panel 110, and if an electrostatic capacity value greater than the reference threshold electrostatic capacity value is generated, may determine that noise has occurred. The threshold electrostatic capacity value may be obtained by experimentally calculating an initial measurement value when no touch has occurred on the electrostatic capacity type touch panel 110 running in an ON state and a value being changed by a surrounding environment and subtracting or adding the changed value from or to the initial measurement value. The noise sensing unit 120 may detect the occurrence of noise using various methods.

If noise is sensed, the noise sensing unit 120 may generate a noise flag (or a noise indicator) to inform the control unit 130 of the occurrence of noise by transmitting the noise flag to the control unit 130. For example, if noise has occurred, the noise sensing unit 120 may generate a noise flag having a value of “1” and transmit the noise flag to the control unit 130.

The control unit 130 may be configured to control the overall operation of the noise cancellation apparatus 100. The control unit 130 may act as a touch controller that operates the noise cancellation apparatus 100 according to the changes in an electrostatic capacity value detected in the electrostatic capacity type touch panel 110. For example, the control unit 130 may detect a touch of the user according to the changes in an electrostatic capacity value detected while running an application, and execute a specific function of the application based on a detected touch position.

The noise sensing unit 120 and the control unit 130 may be arranged on a system board. If the noise cancellation apparatus 100 is implemented as a user terminal device, a system board may have a variety of modules, such as a memory module, a communication module, and the like, for use in various data processes and data communication. The system board may include a first grounding unit (not illustrated) which operates as an internal ground or a board ground of the noise cancellation apparatus 100. Typically, the first grounding unit provides a reference potential of the system board, but if the reference potential is unstable due to effects of external noise on the first grounding unit, the control unit 130 may erroneously detect a touch.

The control unit 130 may generate a switching control signal to control discharge of noise according to the noise flag. In response to the switching control signal, the switching unit 140 may be switched on or off.

In FIG. 1, the noise sensing unit 120 and the control unit 130 are illustrated as separate units. However, the noise sensing unit 120 and the control unit 130 may be integrated as a single unit, or the operations of the noise sensing unit 120 and the control unit 130 may be performed, in whole or in part, by a different unit, such as a main processor of the terminal device in which the noise cancellation apparatus 100 is incorporated.

The first grounding unit of the system board on which the noise sensing unit 120 and the control unit 130 are arranged is connected to the ground connection terminal 150, which may contact the second grounding unit 160 if the switching unit 140 is switched on. Upon switching on the switching unit 140, the first grounding unit of the system board may be connected to the ground connection terminal 150, and thereby be connected to the second grounding unit 160 that provides an external earth ground.

The second grounding unit 160 which is connected to the first grounding unit of the system board according to the switching control signal may provide a noise discharge path. The second grounding unit 160 may be a ground positioned outside of the system board. The second grounding unit 160 may provide a ground potential, such as zero volts (0V). In an embodiment, if the user holds the noise cancellation apparatus 100, thereby being in contact with the second grounding unit 160, it is possible to provide the ground to the noise cancellation apparatus 100 through the user's body.

The second grounding unit 160 may be made of a conductive material. In one example, the second grounding unit 160 may be integrated with or connected to an external metal case of a terminal device having the noise cancellation apparatus 100. The second grounding unit 160 may include an internal extension extending from the external metal case to be connected to the switching unit 140. The internal extension may be integrated with the external metal case.

Hence, in response to the switching unit 140 being switched on, the first grounding unit of the system board is connected to the second grounding unit 160 integrated with the external metal case, thereby enabling discharge of noise that affects the system board to ground. The configuration of the control unit 130 illustrated in FIG. 1 contributes to the ground stabilization of the control unit 130, which may prevent or reduce a risk of an erroneous touch operation.

In absence of external noise, the control unit 130 may generate a switching control signal to switch off the switching unit 140, and thus, the first grounding unit is disconnected from the ground connection terminal 150, and is consequently also disconnected from the second grounding unit 160.

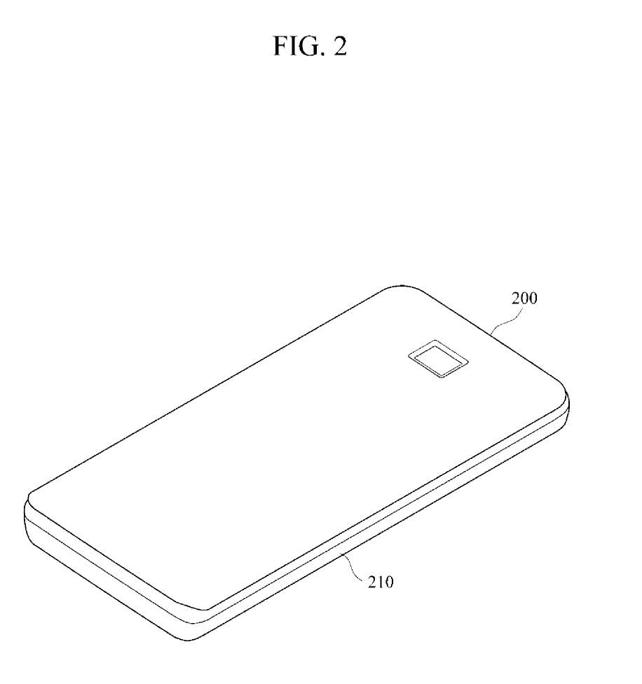

FIG. 2 is a schematic diagram of an external metal case of a terminal device according to an exemplary embodiment of the invention.

FIG. 2 illustrates the noise cancellation apparatus 100 illustrated in FIG. 1 which is implemented in a terminal device 200. A part 210 of the case of the terminal device 200 may be made of a metallic material. Hereinafter, the metallic part 210 of the case will be referred to as metallic case portion 210. The metallic case portion 210 may correspond to the second grounding unit 160, illustrated in FIG. 1, which provides a ground. The metallic case portion 210, as illustrated in FIG. 2, may be arranged along the edge of the case of the terminal device 200. The shape of the second grounding unit 160 may be a shape that can contact with the user's body. By way of example, the metallic case portion 210 operating as the second grounding unit 160 may be disposed at the rear of the terminal device 200, or disposed as an exterior part of the terminal device 200 for design purposes.

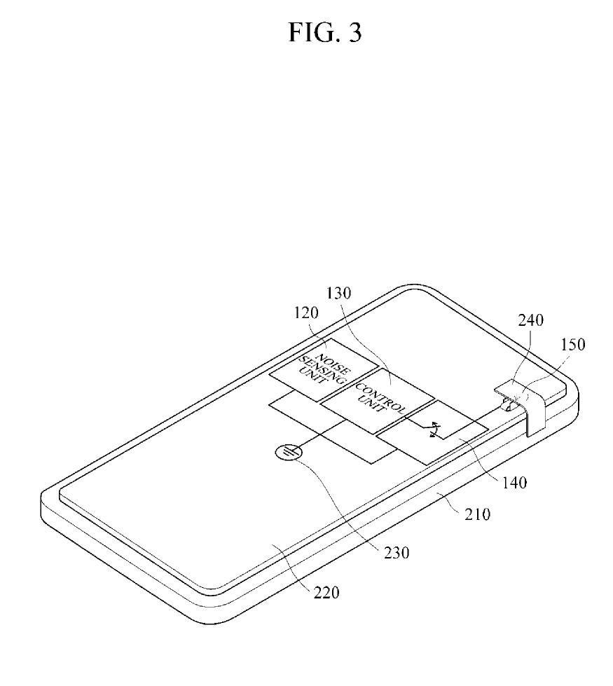

FIG. 3 is a schematic diagram illustrating a second grounding unit according to an exemplary embodiment of the invention.

As shown in FIG. 3, a noise sensing unit 120, a control unit 130 and a switching unit 140 are arranged on a system board 220. The system board 220 includes a first grounding unit 230 as an internal ground. Although not illustrated in FIG. 3, the electrostatic capacity type touch panel (not illustrated) is connected to the noise sensing unit 120 and the control unit 130. The switching unit 140 may be switched on or off according to a switching control signal from the control unit 130, thereby connecting or disconnecting the first grounding unit 230 of the system board 220 to or from a ground connection terminal 150, respectively.

The metallic case portion 210 that is in contact with the user's body, i.e., a hand, may include an internal extension 240 to connect to the ground connection terminal 150 when the switching unit 140 is switched on. The second grounding unit 160, of FIG. 1, may correspond to a configuration including the metallic case portion 210 and the internal extension 240.

Accordingly, the second grounding unit 160 that provides the ground potential through the user's hand shares a ground with the first grounding unit 230 of the system board 220, and thus a ground potential of the first grounding unit 230 can be stabilized even if noise is inserted. Thereby the control unit 230 may prevent or reduce the risk of an erroneous operation in the electrostatic capacity type touch panel and hence may more accurately detect a touch signal from the user on the electrostatic capacity type touch panel.

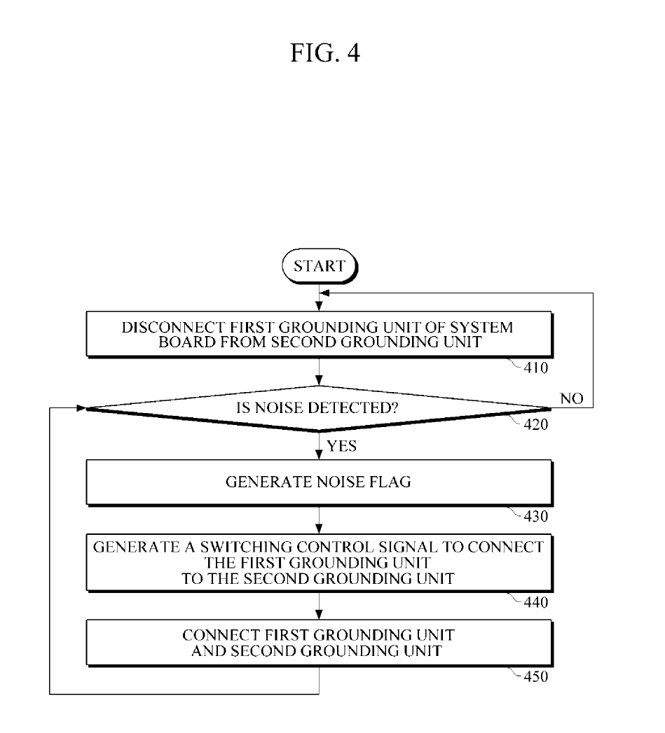

FIG. 4 is a flowchart illustrating a method for canceling noise according to an exemplary embodiment of the present invention.

In operation 410, a noise cancellation apparatus disconnects an internal first grounding unit of a system board from an external second grounding unit.

In operation 420, the noise cancellation apparatus detects noise occurring on an electrostatic capacity type touch panel. In operation 430, in response to a sensed noise, the noise cancellation apparatus generates a noise flag that indicates the occurrence of noise. In absence of noise, the operation 410 is maintained.

In operation 440, the noise cancellation apparatus generates a switching control signal to control the first grounding unit to connect to the second grounding unit. The first grounding unit provides an internal ground to the system board equipped with a control unit that senses a user's touch and the second grounding unit provides a noise discharge path. The second grounding unit may be configured to be external to the system board and provide a ground potential. The second grounding unit to be integrated with an external metal case of a terminal device equipped with an electrostatic capacity type touch panel. The second grounding unit may include an internal extension extending from the external metal case to connect to a switching unit in response to the switching unit being switched on.

In operation 450, the first grounding unit is connected to the second grounding unit in response to the switching control signal, thus the noise cancellation apparatus discharges noise to stabilize a potential of the first grounding unit.

The process returns to noise sensing operation 420, and in response to sensing noise, the operation 430, operation 440, and operation 450 may be repetitively performed. The noise sensing operation 420 may be performed independent of the operation 410, operation 430, operation 440, and operation 450 or at regular intervals.

As illustrated in the above examples, it is possible to prevent or reduce the risk of an erroneous touch operation by electrically connecting an external conductive component that can be in contact with a ground through a user's hand to a ground of a terminal internal circuit board, thereby stabilizing a ground of a terminal using hardware if noise occurs.

It will be apparent to those skilled in the art that various modifications and variations can be made in the present invention without departing from the spirit or scope of the invention. Thus, it is intended that the present invention cover the modifications and variations of this invention provided they come within the scope of the appended claims and their equivalents.

What is claimed is:

1. A noise cancellation apparatus of an electrostatic capacity type touch panel, comprising:
a noise sensing unit to sense noise in the electrostatic capacity type touch panel;
a first grounding unit to provide an internal ground to the electrostatic capacity type touch panel if a noise is sensed;
a second grounding unit to provide an external ground to the electrostatic capacity type touch panel if a noise is sensed.

2. The apparatus of claim 1, wherein the first ground unit is connected to the second ground unit.

3. The apparatus of claim 2, further comprising:
a control unit to generate a switching signal to connect the first grounding unit to the second grounding unit.

4. The apparatus of claim 3, further comprising:
a switching unit to connect the first grounding unit to the second grounding unit.

5. The apparatus of claim 3, wherein the control unit generates a switching signal if the sensed noise is above a reference threshold electrostatic capacity value.

6. The apparatus of claim 4, wherein the noise sensing unit generates a noise flag if the sensed noise is above a reference threshold electrostatic capacity value and transmits the noise flag to the control unit.

7. The apparatus of claim 5, wherein the control unit generates a switching signal to disconnect the first grounding unit from the second grounding unit if the sensed noise drops below the reference threshold electrostatic capacity value.

8. The apparatus of claim 1, wherein the second grounding unit is connected to an exposed metallic component of a case of a terminal device housing the electrostatic capacity type touch panel.

9. A method for canceling noise in a touch panel, comprising:
sensing a noise by a sensing unit;
generating a noise indicator to indicate the occurrence of the noise;
generating a switching signal to connect a first grounding unit to a second grounding unit;
connecting the first grounding unit to the second grounding unit;
if a noise is no longer detected, disconnecting the first grounding unit from the second grounding unit.

10. The method of claim 9, wherein the first grounding unit is an internal ground.

11. The method of claim 9, wherein the second grounding unit is an external ground.

12. The method of claim 9, wherein generating a switching control signal occurs if the sensed noise is greater than a reference threshold electrostatic capacity value.

13. The method of claim 9, wherein generating a noise indicator to indicate the occurrence of the noise signal occurs if the sensed noise is greater than a reference threshold electrostatic capacity value.
